(19) United States
(12) Patent Application Publication
(10) Pub. No.: US 2025/0294874 A1
(43) Pub. Date: Sep. 18, 2025

(54) Analog Cell Structure

(71) Applicant: Taiwan Semiconductor Manufacturing Company, Ltd., Hsinchu (TW)

(72) Inventors: Ming-Cheng Syu, Hsinchu (TW); Yu-Tao Yang, Hsinchu (TW); Wen-Shen Chou, Hsinchu (TW)

(21) Appl. No.: 18/603,469

(22) Filed: Mar. 13, 2024

(51) Int. Cl. H01L 27/118

(52) U.S. Cl. CPC H10D 84/907; H10D 84/929; H10D 84/981

(57) ABSTRACT

Analog circuit devices and methods are provided. An analog circuit device comprises a bottom metal routing layer comprising a plurality of tracks, an analog cell comprising an n-type metal oxide semiconductor (NMOS) active region and a p-type metal oxide semiconductor (PMOS) active region, a plurality of polysilicon layers, and a plurality of metal diffusion layers. In the analog device, the NMOS active region, PMOS active region, plurality of polysilicon layers, and plurality of metal diffusion layers make up a CMOS structure. The device further includes a plurality of guard ring cells surrounding the analog cell and a power rail structure configured to provide connection between the bottom metal routing layer and the analog cell.

### BACKGROUND

Generally, analog designs comprise frontside routing for both signal and power/ground (P/G) delivery. This may lead to a shortage in routing area on the frontside, resulting in a large IR drop. To alleviate this issue, backside signal and/or P/G routing may be provided.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A and 1B are schematic diagrams depicting cross-sections of an integrated circuit device according to an embodiment.

FIG. 2 is a layout diagram depicting the cell structure of an analog circuit according to an embodiment.

FIG. 3A is a top view of a diagram depicting an analog cell design according to an embodiment, FIG. 3B is top view of a diagram depicting an analog cell at a stage during fabrication of an integrated circuit, FIG. 3C is a cross-sectional view depicting the analog cell of FIG. 3B, and FIG. 3D is another cross-sectional view depicting the analog cell of FIG. 3B.

FIG. 4 is a top view of a diagram depicting an analog cell design according to another embodiment.

FIG. 5 is a top view of a diagram of an analog cell and an adjacent vertical guard ring cell according to an embodiment.

FIG. 6 is a top view of a diagram of an analog cell and an adjacent vertical guard ring cell according to an embodiment.

FIG. 7 is a layout diagram of an analog circuit design according to an embodiment.

FIGS. 8A, 8B, and 8C are block diagrams depicting example systems for implementing approaches described herein for designing integrated circuits.

FIG. 9 is a flowchart depicting a method of designing an analog circuit according to an embodiment.

FIGS. 10A-10K depict a method of design and fabricating an integrated circuit device according to an embodiment. FIG. 10A is a flowchart depicting a method of designing and fabricating an integrated circuit device according to an embodiment. FIGS. 10B-10K are schematic diagrams depicting cross-sectional views of a method of fabricating an integrated circuit device according to an embodiment.

FIG. 11 is a flowchart depicting a method of fabricating an integrated circuit according to an embodiment.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in some various examples. This repetition is for the purpose of simplicity and clarity and does not in itself dictate a relationship between some various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the circuit. Some of the features described below can be replaced or eliminated for different embodiments. Although some embodiments are discussed with operations performed in a particular order, these operations may be performed in another logical order.

As described above, analog circuits may comprise frontside P/G and signal routing that creates a routing area shortage and a large IR drop. As one solution, a feed-through via (FTV) may be inserted that allows for backside routing of P/G or signal routing such that the FTV connects the backside routing to frontside interconnects. However, FTV insertion may create a large penalty area (i.e., an area proximate to the FTV in which components cannot be placed without violating design rules or otherwise deteriorating performance). Additionally, a high cut metal gate (CMG) density associated with FTV design may induce process risk.

Embodiments described herein provide solutions for backside signal routing that can avoid these issues. In some embodiments, a super power rail (SPR) structure is provided for a CMOS design that includes FTV and backside P/G support. Additionally, embodiments described herein may employ a dual cut metal gate (CMG) process to avoid high cut poly (CPO) density.

By incorporating these features, devices and layouts described herein may incorporate inter-cell FTVs without incurring an extra area penalty. Additionally, the techniques described herein may result in more uniform parasitic resistance throughout a layout thereby improving mismatch characteristics. Further, by employing backside routing of P/G or signal connection and more specifically, exemplary SPR structures having a feed-through via and backside via, embodiments described herein may result a lower IR drop.

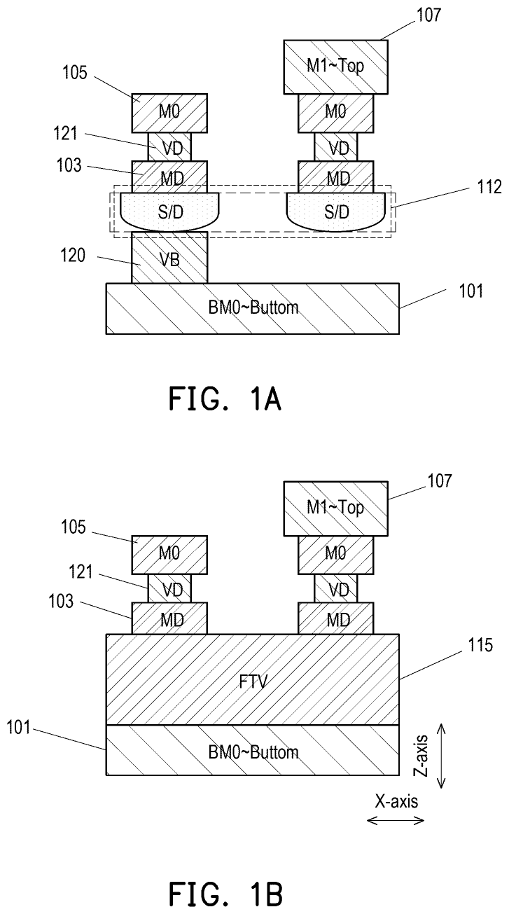

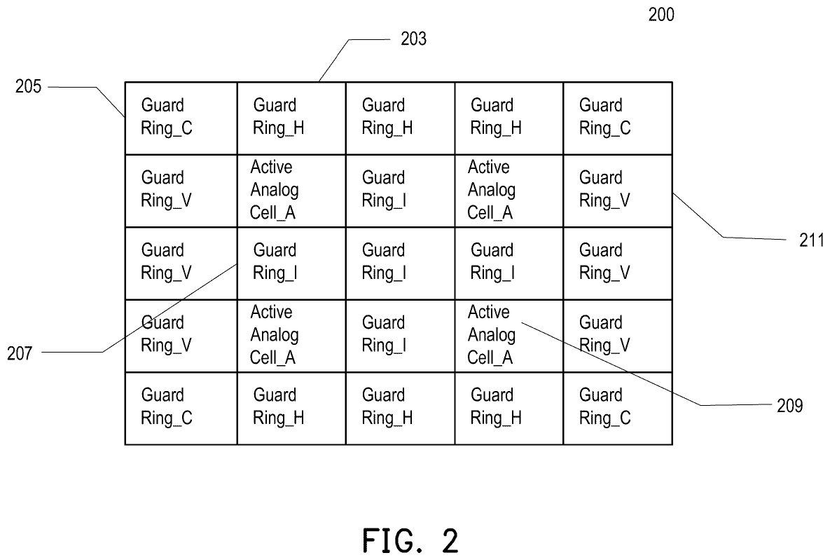

FIG. 1 is a schematic diagram depicting cross-sections of an integrated circuit device according to embodiments. As described above, in some integrated circuits, both P/G and signal connections are routed on the frontside of a device. However, this may cause large IP drop and low routing flexibility. By incorporating FTV and backside via (VB) structures, these issues may be overcome. For example, as shown in FIG. 1A, a device may comprise a transistor having source/drain (S/D) elements 112. The S/D elements 112 may be connected a series of conductive interconnects that provide signal and P/G routing. The interconnect structure may comprise a stack of metal routing layers and a series of vias vertically connecting the metal routing layers.

In an embodiment, a backside via (VB) 120 may provide backside routing between the S/D elements 112 and a bottom metal routing layer (BM0) 101 of the interconnect structure. Backside via 120 may provide P/G or signal routing for the S/D elements 112, thereby freeing up routing area on the frontside of the device. The bottom metal routing layer 101 may comprise a plurality of tracks spaced apart from one another. Backside vias and feed-through vias may provide backside routing from the plurality of tracks to structures of the device.

On the frontside, the S/D elements 112 may be connected to additional routing through a series of metal routing layers. For example, the interconnect structure may comprise additional metal routing layers MD 103, M0 105, and M1 107. M1 may be top layer of the structure. In an embodiment, metal routing layers MD may metal contact pattern for connecting a semiconductor material of the S/D elements. The metal routing layers may be connected by vias. For example via VD 121 may connect metal routing layer MD to metal routing layer MO.

FIG. 1B depicts a cross-section of the device along a feed-through via (FTV) 115. FTV structure 115 may provide a P/G or signal connection between bottom metal routing layer 101 on the backside to another metal routing layer MD on the frontside. In an embodiment, FTV 115 and backside via 120 support a power rail structure for backside power delivery to a device that results in a lower IR drop.

FIG. 2 is a layout diagram depicting the cell structure of an analog circuit according to an embodiment. The layouts described herein may allow for incorporation of the P/G and/or signal connections described above into increasingly smaller device and node sizes while passing design rule checks.

The design process for an analog circuit according to embodiments may use fundamental building blocks called cells in order to create complex circuits. Cells may include pre-determined, standard architecture that is selected to provide a specific function. These cells may include active analog cells 209 that provide functionality for the analog circuit. The cells may also include guard ring cells 203, 205, 207, and 211 that surround the analog cells to provide protection and isolation for the analog cells.

The analog cells and guard ring cells may be arranged in an array comprising rows and columns. In a non-limiting example, the array may comprise three rows and four columns as shown in FIG. 2.

In an embodiment, the layout may comprise a plurality of analog cells 209. These cells comprise specific arrangements of transistors, capacitors, or other components sufficient to provide a designated analog function. For example, the analog cells may comprise amplifiers, regulators, comparators, filters, or any other type of analog cell as called for by the specific design. Architectures for the analog cells may be stored in, and recalled from, an analog cell library, allowing designers of the initial design to create complicated and densely packed integrated circuits with reduced time and effort.

Each analog cell may be surrounded by a guard ring comprising a plurality of guard ring cells. For example, each analog cell 209 may be adjacent to eight guard ring cells so as to fully surround each analog cells. Similar to the analog cells, the guard ring cells may comprise a specific arrangement of internal components sufficient to function as part of a guard ring, and the structure of these may be stored in a library and recalled by a designer to generate an analog integrated circuit layout.

The guard ring cells may be divided into corner guard ring cells 205, vertical guard ring cells 211, horizontal guard ring cells 203, and inner guard ring cells 207 based on their location within the layout. The position of the guard ring cell may determine the structures or layout of structures within the cell. Fully surrounding each analog cell with guard ring cells may protect the analog cells against noise and may allow the circuit to meet latch-up requirements. Corner guard ring cells 205, horizontal guard ring cells 203 and vertical guard ring cells 211 may make up an outer border of the array of cells.

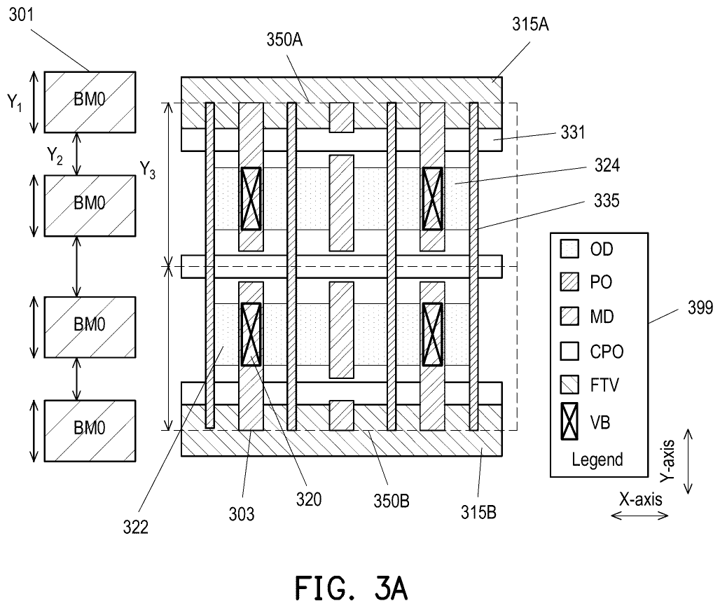

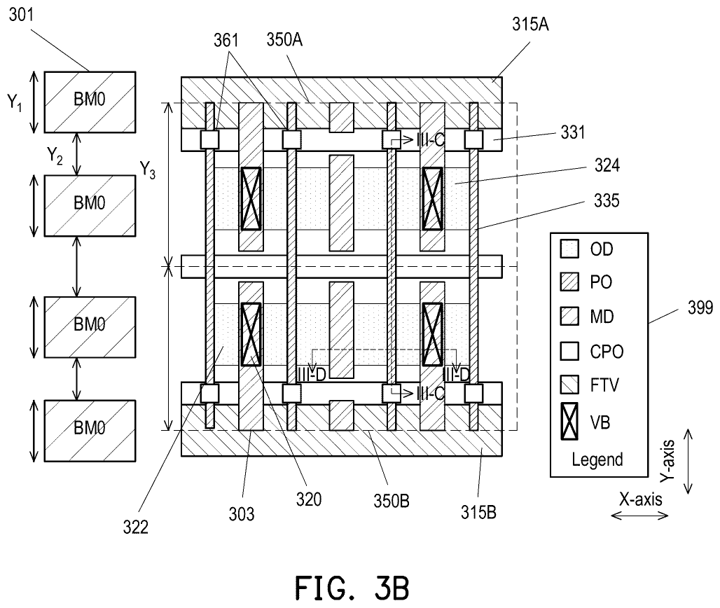

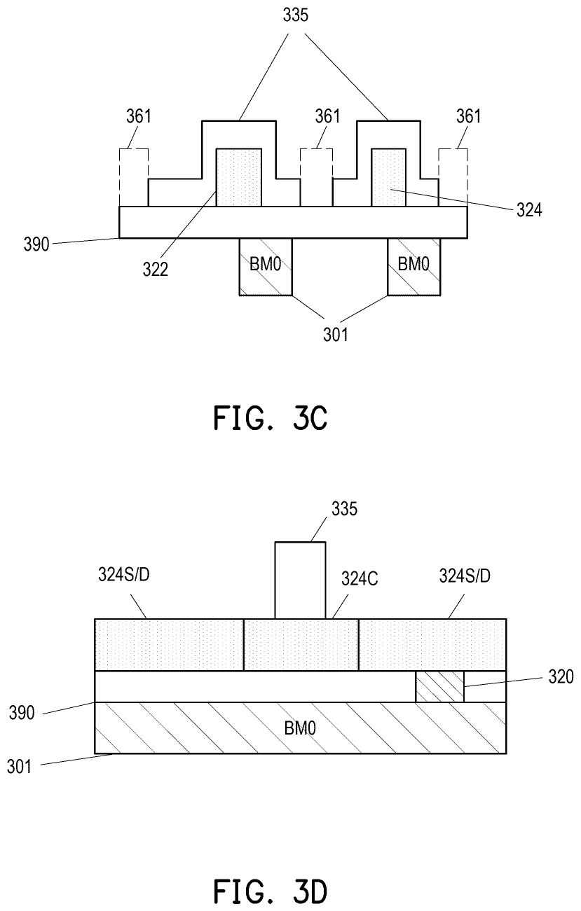

FIGS. 3A-3D depict views of an analog cell according to embodiments. FIG. 3A depicts a top view of a diagram depicting an analog cell design according to an embodiment. Legend 399 provides a guide for understanding structures within the design.

In an embodiment, the design may include a power rail structure comprising FTVs 315 and backside vias (VB) 320. The analog cell design may further comprise bottom metal routing layer tracks (BM0) 301 that extend in a first direction. The bottom tracks 301 may each comprise a first length in the second direction Y₁, and the spacing between tracks may comprise a second length in the second direction Y₂. In an embodiment, the second length may be greater than the first length. Spacing between the bottom tracks 301 may be set according to specific design rules. For example, in an embodiment, Y₁ may be 36 nm or less and Y₂ may be 40 nm or less.

FTVs 315 and backside vias 320 may provide P/G and signal connection to components within the cell. For example the analog cell may further comprise a plurality of polysilicon (PO) layers 335, a plurality of active regions 322/324, a plurality of metal contact (MD) patterns 303. The PO layers 335 may extend over the active regions 322/324 to form a poly over diffusion edge (PODE) structure, which may allow for increased densification in the design.

The design layout for the analog cell may further comprise cut poly areas (CPO) 331. The MD patterns 303 may provide routing to and from components of the analog cell. For example, the FTVs 315 and backside vias 320 may provide P/G and/or signal connections from the bottom metal routing layer to components of the analog cell. In an embodiment, a process design kit used to generate the cell design may comprise a common description format (CDF) that allows a user to turn on and off the CPO areas or to change the CPO area to cut metal diffusion (CMD) area.

CPO and CMD regions may comprise areas within an IC design that remove polysilicon (PO) and metal diffusion (MD), respectively, from the areas of the design in which the CPO and CMD layers are disposed. In an embodiment, an IC design tool such as an electronic design automation (EDA) or computer-aided design (CAD) tool may generate a design based on input instructions or a desired structure. A design generated by these tools may include CPO and CMD regions that intersect PO and MD layers within the design. The CPO and CMD layers may result in the PO and MD layers being removed from this intersecting area during later stages in the process of fabricating an integrated circuit from the design. Using CPO and CMD regions may allow for reduced spacing in the design without violating design rules.

In an embodiment, a method of designing and fabricating an integrated circuit may comprise forming a first polysilicon pattern. This pattern may correspond to the pattern of PO layers as shown in FIG. 3, for example. The method may further comprise forming a CPO pattern comprising a plurality of CPO regions. The CPO pattern may be formed so as to create a plurality of overlaps between the first polysilicon pattern and the CPO pattern. During fabrication, polysilicon may be removed from these overlaps regions, thereby forming a second polysilicon pattern. The second polysilicon pattern may enable the formation of a CMOS structure, as will be described in greater detail below.

The analog cell may be bordered on each in the second direction by a first FTV 315A and a second FTV 315B. When the analog cell design is manufactured, the cut poly areas 331 may cause PO layers to be removed from these areas. Accordingly, a central cut poly area may divide the analog cell into two subregions 350A, 350B. Additionally, the central cut poly area may bisect each of the plurality of PO layers into two PO segments, one in first subregion 350A and one in second subregion 350B. Each subregion may comprise a third length in the second direction Y₃. In an embodiment, third length Y₃ may represent one-half of the total cell height. For example, the cell may comprise a total cell height of 260 nm, and the third length Y₃ may comprise 130 nm.

In an embodiment, the analog cell may comprise a complimentary metal oxide semiconductor (CMOS) layout wherein the first subregion 350A comprises one of a p-type metal oxide semiconductor (PMOS) region and a n-type metal oxide semiconductor (NMOS) region, and the second subregion 350B comprises the other of the PMOS and NMOS region. The PMOS and NMOS regions may comprise PMOS and NMOS transistors having source/drain structures.

A device fabricated based on the design of FIG. 3 may comprise a CMOS device comprising the structures as shown with the PO layers 335 removed in positions corresponding to CPO regions. In an example, the source/drain structures may be similar to those described above with reference to FIG. 1. A backside via 320 may provide backside routing between a source/drain structure located in the active regions 322/324 and a bottom metal. A portion of MD patterns 303 may contact the source/drain structure on the opposite side of the backside via, thereby providing frontside routing. By incorporating backside routing through FTV structures 315 and backside vias 320, more area is available for frontside routing to and from devices within the analog cell.

FIG. 3B is top view of a diagram depicting an analog cell at a stage during fabrication of an integrated circuit according to an embodiment. FIG. 3B may depict the analog cell after polysilicon is removed from overlap regions with CPO regions. Reference number 361 may represent areas where PO layers have been removed. While FIG. 3B shows 361 as pointing to only two such areas, the figure shows a plurality of additional boxes indicating previous overlap regions, indicating that the removal may occur in any area where there was overlap between PO and CPO.

FIG. 3C is a cross-sectional view depicting a cross-section along line III-C as shown in FIG. 3B. This cross-section may be taken along a PO layer 335 of the plurality of PO layers. In an embodiment, the bottom metal routing layer tracks (BM0) 301 may be separated from structures of the analog cell by a substrate 390. For example, active regions 322/324 may comprise active fins and substrate 390 may be insulative. In another embodiment, substrate 390 may comprise a silicon-on-insulator (SOI) structure and may comprise a silicon substrate with a buried insulator layer between the silicon substrate and the active regions.

Active regions 322/324 may be formed over the substrate 390. The PO layer 335 may be formed to extend across both active region 322 and active region 324. In an embodiment, the PO layer 335, as initially generated during a method of designing an analog, may extend completely across the cross-section along line III-C of FIG. 3B. Regions where PO layer 335 intersects with CPO regions of the design, however, may be removed resulting in the disposition of PO layer 335 depicted in FIG. 3C. Removal areas 361 indicate areas where the PO layer 335 overlapped with CPO regions of the design.

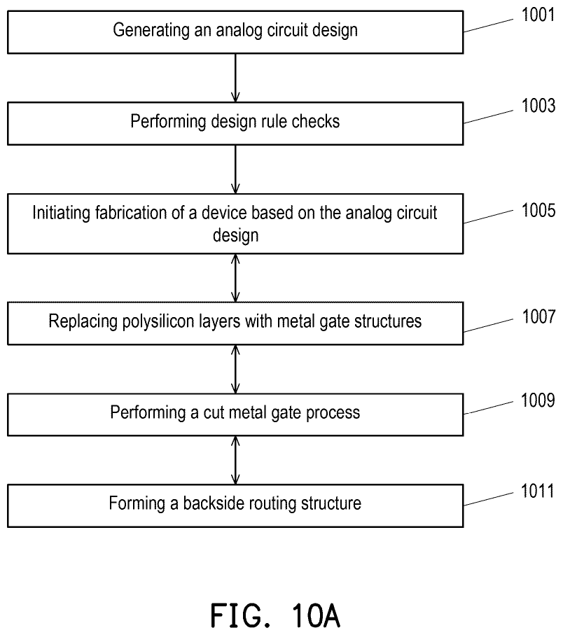

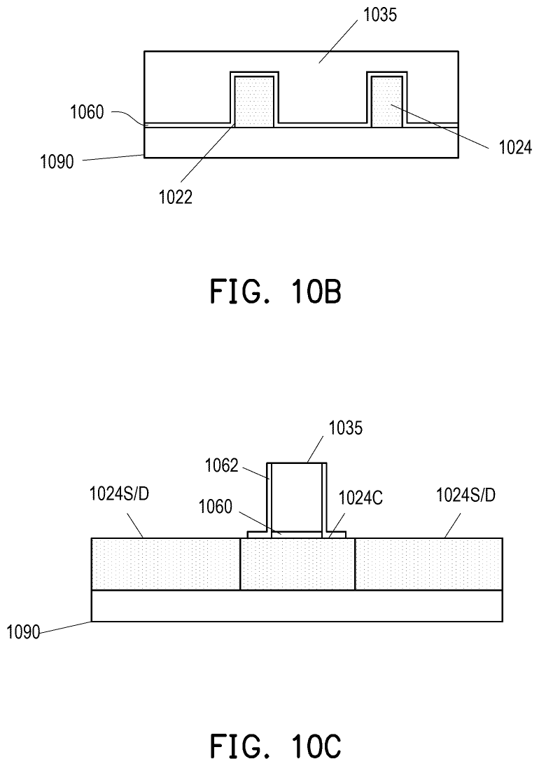

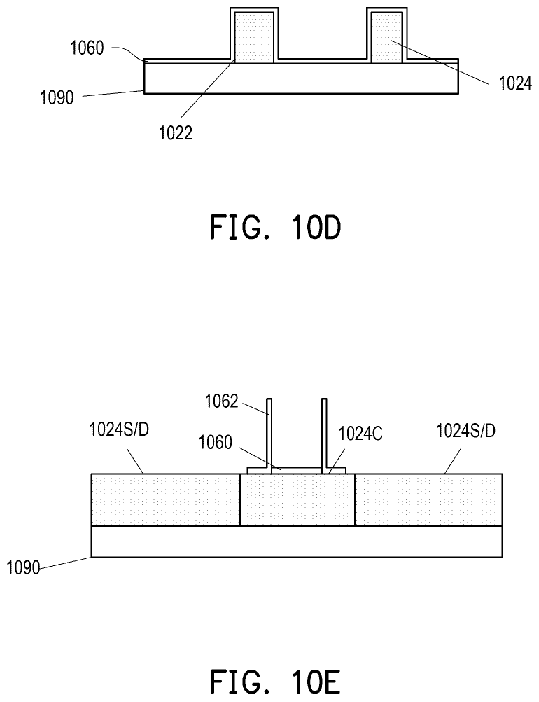

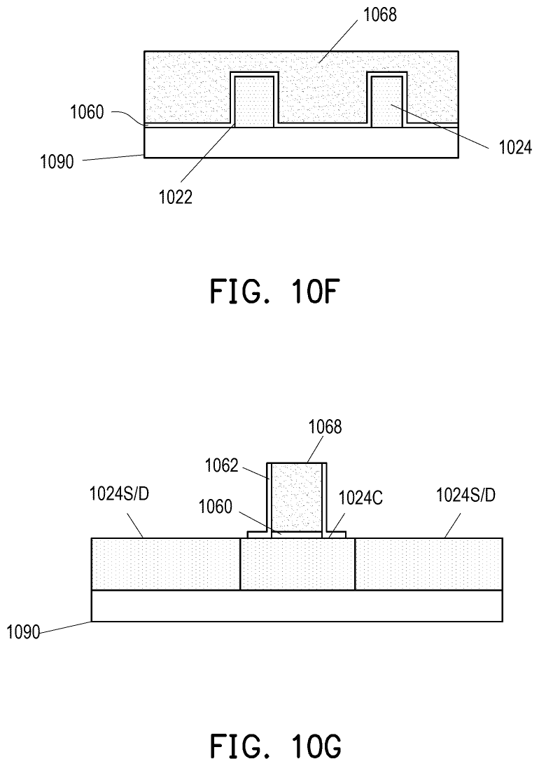

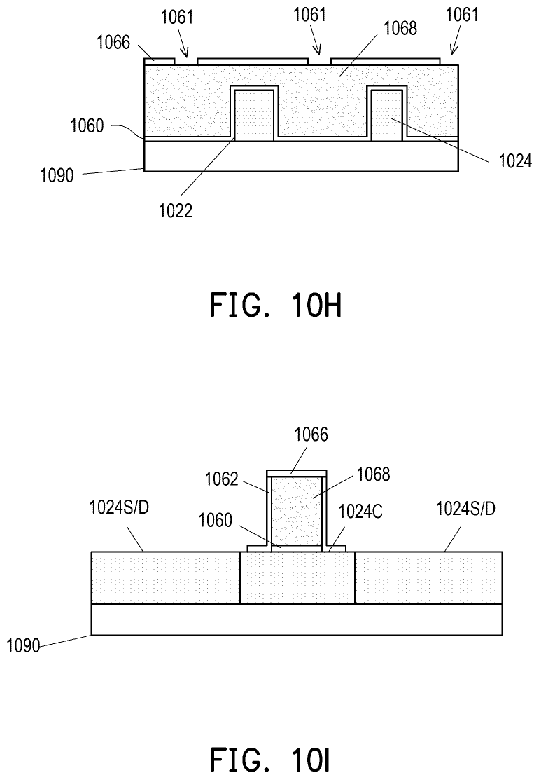

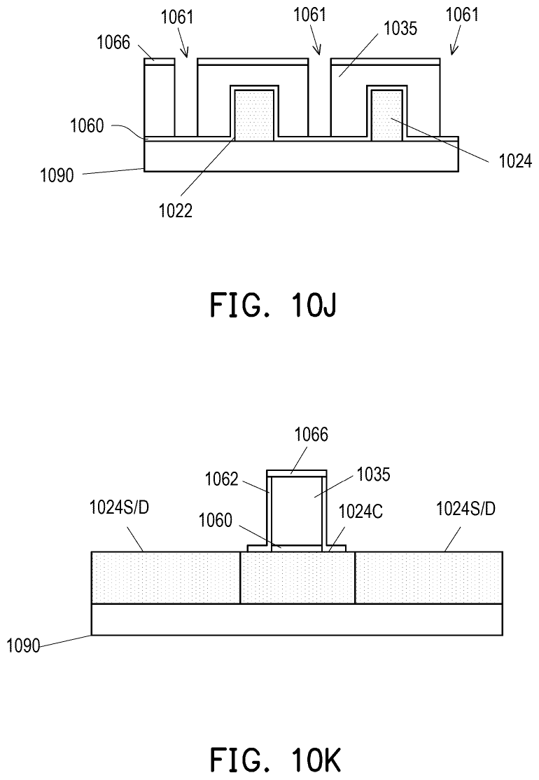

In another embodiment, described in greater detail with respect to FIGS. 10B-10K below, the PO layer 335 may be an intermediate layer. For example PO layer 335 may be one of a plurality of dummy electrodes and these dummy electrodes may be replaced by metal gate electrodes.

FIG. 3D is a cross-sectional view depicting a cross-section along line III-D as shown in FIG. 3B. Along this line, a single track of the bottom metal routing layer (BM0) 301 may extend below active region 324. Active region 324 may be separated from the bottom metal routing layer track 301 by a substrate 390. As described above, in an embodiment, active region 324 may comprise an active fin and substrate 390 may comprise an insulator or a SOI structure. Active region 342 may further comprise source/drain regions 324S/D and a channel region 324C. As a part of the backside metal routing provided by embodiments described herein, a backside via 320 may provide a connection between bottom metal routing layer 301 and a source/drain 324S/D of the active region 324. PO layer 335 may be formed over the channel region 324C of the active region thereby acting as a gate in a CMOS structure of the analog cell. PO layer 335 and channel region 324C may be separated by a dielectric layer (not shown).

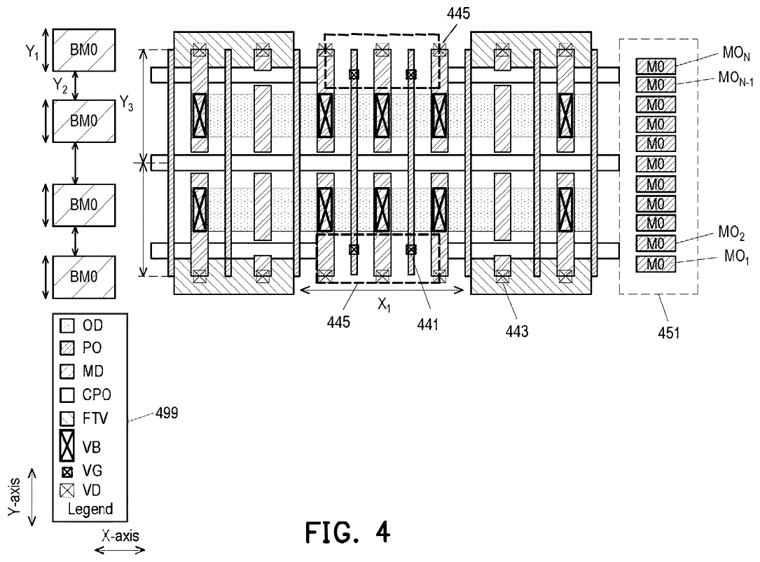

FIG. 4 depicts a top view of a diagram depicting an analog cell design according to another embodiment. Legend 499 provides a guide for understanding structures within the design. Components of analog cell designs depicted in FIG. 4 may be similar to those described above with respect to FIGS. 3A-3D. Accordingly, reference numbers to some structures may be omitted for the purpose of clarity.

In an embodiment, there may be a break in the CPO and FTV layers in order to facilitate PO tie-off. For example, break regions 445 may comprise an area where FTV structures and cut poly are removed from the design. This break region may comprise a horizontal extent X₁ in the first direction.

Accordingly, this provides space for a plurality of second vias (VG) 441 to provide tie-off connection to PO layers. Additionally, the design may include a plurality of third vias (VD) 443 that provide connection to the MD patterns. In an example, vias VG connect to a gate of a transistor of the design and vias VD connect to a drain of a transistor of the design. As described above with reference to FIG. 1, the cell may have a total height of 260 nm. In such an embodiment, the horizontal extent of the break region may be 144 nm. This allows enough space for tie-off without violating design rules.

As shown in FIG. 1 and described above, the design may also comprise an additional metal routing layer M0. In an embodiment, the design may comprise a plurality of M0 layers 451 extending in the first direction and arranged at intervals as shown in FIG. 4. For example, the plurality of layers may comprise N number of layers that can be labeled from M0₁ through M0_{N}. To lower resistance, M0 layers at the edge (M0₁, M0₂, M0_{N-1}, M0_{N}) of the cell may be used as landing points for second vias (VG) or third vias (VD).

Similar to embodiments described above with respect to FIGS. 3A-3D, the analog cell of FIG. 4 may comprise a CMOS structure including NMOS and PMOS active regions. The active regions may comprise a PODE arrangement such that the PO layers extend over the edge of diffusion regions. A device fabricated based on the design of FIG. 4 may comprise a CMOS device comprising the structures as shown with the PO layers removed in positions corresponding to CPO regions. By implementing a SPR structure comprising feed-through and backside vias, power and/or supply signals may be routed to devices of the analog cell through the backside, thereby preserving frontside routing space and improving IR drop.

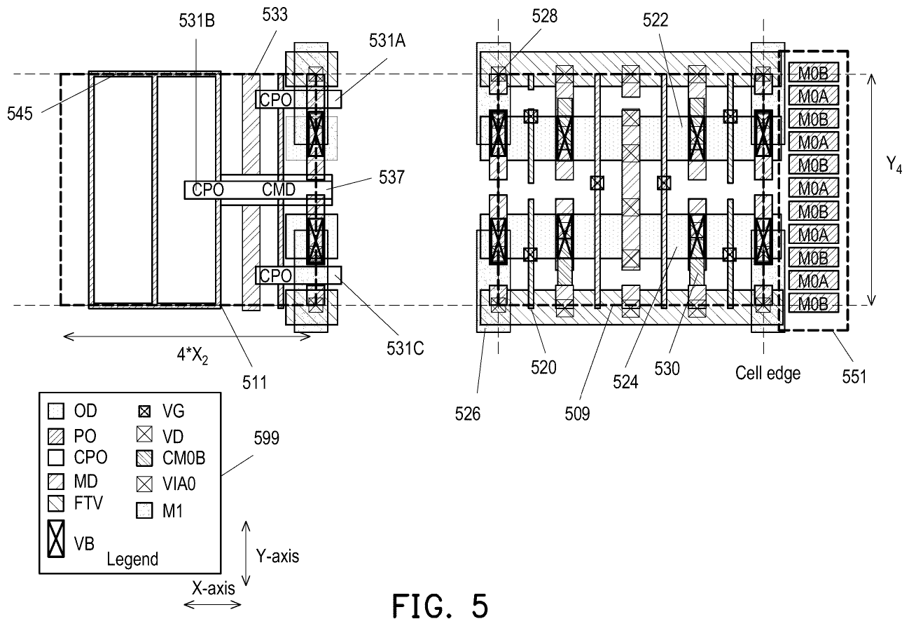

FIG. 5 depicts a top view of a diagram of an analog cell and adjacent vertical guard ring cell according to an embodiment. Legend 599 provides a guide for understanding the structures within the design. The cells depicted in FIG. 5 may be similar to those described above with respect to FIGS. 2 and 4. For clarity, reference numbers and detailed descriptions components which have been already described above may be omitted, while the description below relates to additional structures.

In an embodiment, an analog cell 509 may be disposed adjacent to a vertical guard ring cell 511. Specifically, vertical guard ring cell 511 may be disposed along a left boundary of the layout. It is noted that while FIG. 5 depicts a vertical guard ring cell 511 along a left boundary of the layout, vertical guard ring cells along a right boundary of the layout comprise a similar, but flipped design. In FIG. 5, the cells are shown as separated by empty space, however it is noted that this space is provided for clarity and the cells may directly abut such that features on the left side of cell 509 directly match up with features on the right side of 511.

In addition to layers already described, the embodiment of FIG. 5 may further comprise Tie-PO structures 520, and an upper metal routing layer 526 (M1). Metal routing layer M0 551 of the design may comprise tracks that alternate between a first track M0A and a second track M0B in the second direction. The design may further comprise a cut metal layer 530 configured as a marker to cut the second track M0B (CM0B) within the design. Additionally a plurality of VIA0 vias 528 may be provided to provide routing to the M1 layer. The design may also comprise bottom metal layers BM0 (not shown) similar to those described above. Connection from BM0 layers to analog circuit structures may be made through backside connections via a SPR structure comprising FTVs and VBs.

The analog cell 509 may comprise an inverter structure including PMOS and NMOS devices. For example, analog cell 509 may comprise a PMOS active region 522 and an NMOS active region 524. The active regions 522 and 524 may extend outside the boundary of analog cell 509 and cross over into guard ring cell 511, thereby forming a continuous oxide diffusion (CNOD) region. A device fabricated based on the design of FIG. 5 may comprise a CMOS device comprising the structures as shown with the PO layers removed in positions corresponding to CPO regions and MOB layers removed in positions corresponding to CMOB regions.

Analog cell 509 may comprise a cell height Y₄ in the second direction and the structures therein may define a cut poly pitch (CPP) having a width X₂ in the first direction. In an embodiment, the cell height may be 260 nm.

As described above, guard ring cell 511 may comprise a vertical guard ring cell disposed along the left side of an analog circuit layout. Guard ring cell 511 may directly abut an analog cell, such as cell 509 such that guard ring cell 511 comprises structures from the analog cell (e.g., active regions 522, 524) that extend across the cell boundary. The guard ring cell 511 may further comprise a MD region 533 extending in a second direction from a bottom of the cell to the top of the cell. The guard ring cell 511 may comprise an extent in the first direct that is four times the pitch width X₂ described above with respect to analog cell 509.

The guard ring cell 511 may further comprise a cut metal diffusion region (CMD) 537 and a plurality of cut poly regions (CPO) 531A, 531B, 531C. The CMD and CPO regions may be configured to remove PO and MD regions of the design from specific areas in order to provide protection and isolation to the abutting analog cell. In an embodiment, CMD region 537 may provide a break in MD region 533 during fabrication.

The guard ring cell 511 may also comprise a PO guard ring structure 545. In an embodiment PO guard ring structure 545 may comprise a bounded shape and may comprise additional extensions in the interior. For example, PO guard ring structure 545 may comprise a rectangle with a central interior extension spanning the vertical length of the rectangle. The PO guard ring structure 545 may interface with PO guard ring structures of adjacent guard ring cells so as to form a continuous boundary structure along a boundary of the layout. In an embodiment, PO guard ring structure 545 may be configured to provide protect and isolate an adjacent analog cell.

In another embodiment, PO guard ring structure 545 may undergo a high pressure oxidation (HPO) process to create a boundary area guard ring structure that provides protection and isolation to a surrounded analog cell. As such, the guard ring structure may be insulative.

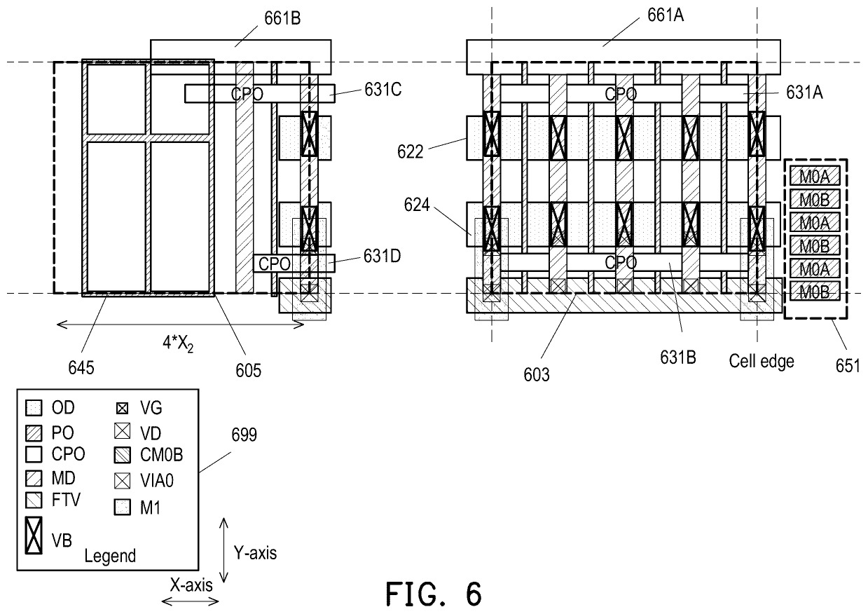

FIG. 6 is a top view of a diagram of a horizontal guard ring cell 203 and adjacent corner guard ring cell 605 according to an embodiment. Legend 699 provides a guide for understanding the structures within the design. The cells depicted in FIG. 6 may be similar to those described above with respect to FIGS. 2. Specifically, FIG. 6 may depict a top left corner cell of the layout of FIG. 2 and a horizontal guard ring cell adjacent thereto. For clarity, reference numbers and detailed descriptions components which have been already described above may be omitted, while the description below relates to additional structures.

In an embodiment, a horizontal guard ring cell 603 disposed in the top row of an analog circuit layout may be disposed adjacent to a corner guard ring cell 605 disposed in the top left corner of an analog circuit layout. It is noted that while FIG. 6 depicts top and top left cells, bottom cells may comprise a similar, but flipped design cell 603, and other corner cells may comprise a similar, but flipped design from cell 605. In FIG. 6, the cells are shown as separated by empty space, however it is noted that this space is provided for clarity and the cells may directly abut such that features on the left side of cell 603 directly match up with features on the right side of 605.

Horizontal guard ring cell 603 may abut an analog cell positioned directly below it, and accordingly the bottom of horizontal guard ring cell 603 may interface with a FTV of the analog cell. In an embodiment, the horizontal guard ring cell may comprise similar structures to that of the analog cell described above with respect to FIG. 5 including PO layers, pick up active regions 622 and 624, MD regions, and M0 tracks M0A and M0B 651. The design may also comprise bottom metal layers BM0 (not shown) similar to those described above.

Additionally, horizontal guard ring cell 603 may comprise a plurality of cut poly (CPO) regions 631A, 631B and a cut metal diffusion (CMD) region 661A. As described above, the CPO and CMD regions may instruct design and fabrication tools to remove PO and MD regions, respectively, from these regions. This technique may allow for the design to have reduced spacing without violating design rules. In an embodiment, the two CPO regions 631A, 631B may provide a dual cut metal gate (CMG) structure during fabrication. For example, during fabrication polysilicon layers of the analog cell may be replaced with metal gate structures, and may then undergo a metal gate cut process along the CPO regions. This dual structure may reduce the density CPO region in the cell, and correspond reduce a density of the region where the cut metal gate process takes place, thereby reducing process risk associated with CMG density. In an embodiment, these fabrication techniques may enable a reduced pitch between OD regions. For example, a space between adjacent OD regions Y₄ may comprise a width of 46 nm or less.

In an embodiment, corner guard ring cell 605 may comprise similar components to the vertical guard ring cell described above with respect to FIG. 5. For example, corner guard ring cell 605 may abut adjacent cell 603 and may comprise CPO regions 631C, 631D and a CMD region 661B interfacing with the cell edge. CMD region 661B may be continuous with CMD region 661A. CPO region 631C may be continuous with CPO region 631A and CPO region 631D may be continuous with CPO region 631B.

Corner guard ring cell 605 may further comprise a PO guard ring structure 645. In an embodiment, PO guard ring structure 645 may comprise a similar shape to that of the PO guard ring structure described above with respect to FIG. 5. PO guard ring structure 645 may terminate along an upper edge of corner guard ring cell 605, and may interface with the PO guard ring structure of a vertical guard ring cell positioned below corner guard ring cell 605. As such, the guard ring cells may create a continuous boundary area structure along sides of an analog circuit design. In an embodiment, PO guard ring structure 645 may be configured to provide protect and isolate an adjacent analog cell.

In another embodiment, PO guard ring structure 645 may be an intermediate structure formed during design of an analog circuit that is later removed or altered during fabrication of a circuit. For example, PO guard ring structure 645 may undergo a high pressure oxidation process (HPO) to form an insulative guard ring structure.

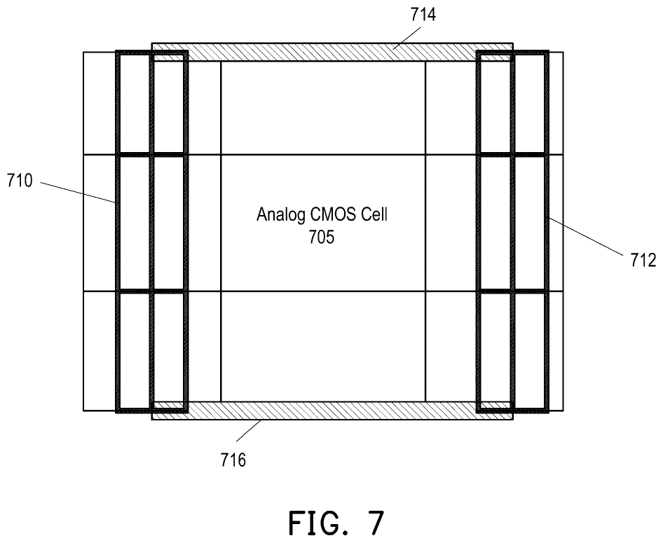

FIG. 7 is a layout diagram of an analog circuit design according to an embodiment. An analog CMOS cell 705 may be bounded on all sides by guard ring cells. Analog CMOS cell 705 may comprise a SPR structure including FTVs and backside vias so as to provide backside delivery of P/G and/or signal connections to the cell.

The guard ring cells may comprise four corner guard ring cells, two vertical guard ring cells, and two horizontal guard ring cells so as to surround analog CMOS cell 705. In an embodiment, the corner and vertical guard ring cells may comprise guard ring structures, similar to the PO guard ring structures described above, that interface with each other so as to form continuous boundary area structures 710 and 712. Corner guard ring cells and horizontal guard ring cells may comprise cut metal diffusion (CMD) regions 714 and 716 that extend horizontally along top and bottom edges of the layout so as to remove any undesired metal diffusion material from those regions.

An integrated circuit device fabricated from the design of FIG. 7 may include the structures shown with the CMD regions configured to indicate removal of material from those regions. Guard ring structures 710, 712 may comprise PO guard rings that may be later removed and replaced, or otherwise altered to form insulative boundary area structures.

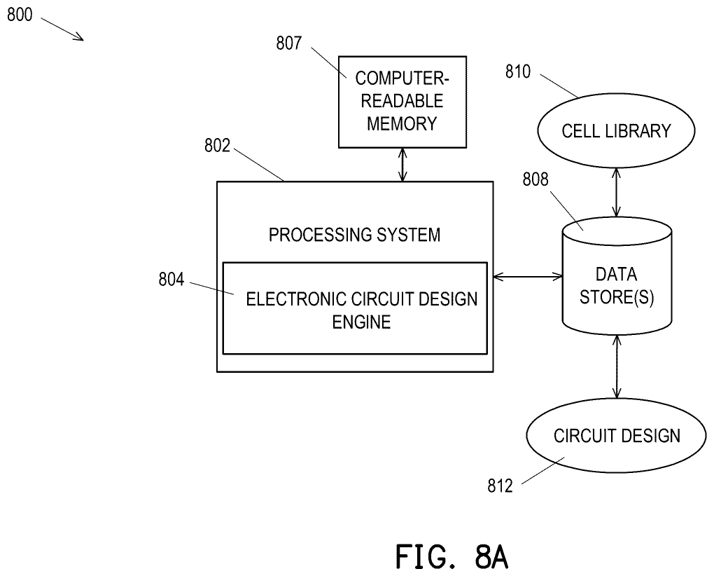

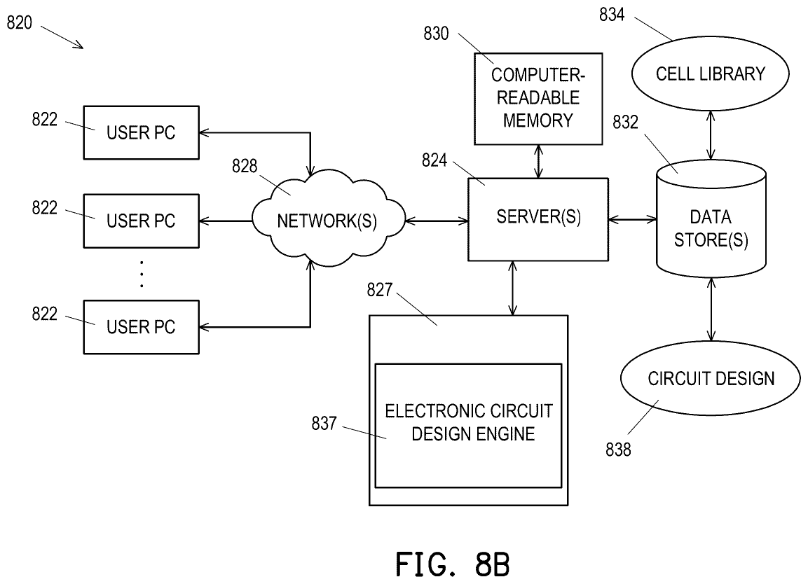

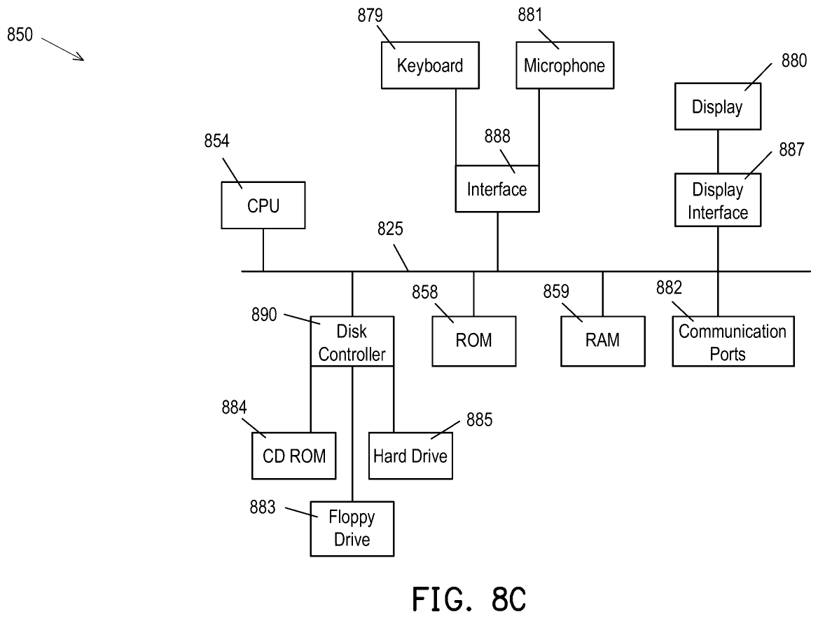

FIGS. 8A, 8B, and 8C depict example systems for implementing the approaches described herein for designing integrated circuits. For example, FIG. 8A depicts an exemplary system 800 that includes a standalone computer architecture where a processing system 802 (e.g., one or more computer processors located in a given computer or in multiple computers that may be separate and distinct from one another) includes a computer-implemented electronic circuit design engine 804 being executed on the processing system 802. The processing system 802 has access to a computer-readable memory 807 in addition to one or more data stores 808. The one or more processors of processing system 802 may be in communication with the computer-readable memory 807 which may store instructions that, when executed, command the one or more processors to execute the operations of the methods described herein. The one or more data stores 808 may include a cell library database 810 as well as a circuit design database 812. In an embodiment, cell library database 810 may comprise an analog cell library. The processing system 802 may be a distributed parallel computing environment, which may be used to handle very large-scale data sets.

FIG. 8B depicts a system 820 that includes a client-server architecture. One or more user PCs 822 access one or more servers 824 running an electronic circuit design engine 837 on a processing system 827 via one or more networks 828. The one or more servers 824 may access a computer-readable memory 830 as well as one or more data stores 832. The one or more data stores 832 may include a cell library database 834 as well as a circuit design database 838.

FIG. 8C shows a block diagram of exemplary hardware for a standalone computer architecture 850, such as the architecture depicted in FIG. 8A that may be used to include and/or implement the program instructions of system embodiments of the present disclosure. A bus 852 may serve as the information highway interconnecting the other illustrated components of the hardware. A processing system 854 labeled CPU (central processing unit) (e.g., one or more computer processors at a given computer or at multiple computers), may perform calculations and logic operations required to execute a program. A non-transitory processor-readable storage medium, such as read only memory (ROM) 858 and random-access memory (RAM) 859, may be in communication with the processing system 854 and may include one or more programming instructions for performing the method of designing an integrated circuit. Program instructions may be stored on a non-transitory computer-readable storage medium such as a magnetic disk, optical disk, recordable memory device, flash memory, or other physical storage medium.

In FIGS. 8A, 8B, and 8C, computer readable memories 807, 830, 858, 859 or data stores 808, 832, 883, 884, 888 may include one or more data structures for storing and associating various data used in the example systems for designing an integrated circuit. For example, a data structure stored in any of the aforementioned locations may be used to store data from XML files, initial parameters, and/or data for other variables described herein. A disk controller 890 interfaces one or more optional disk drives to the system bus 852. These disk drives may be external or internal floppy disk drives such as 883, external or internal CD-ROM, CD-R, CD-RW, or DVD drives such as 884, or external or internal hard drives 885. In addition to physical drives, the system bus 852 may be in communication with cloud-based virtual drives. As indicated previously, these various disk drives and disk controllers are optional devices.

Each of the element managers, real-time data buffer, conveyors, file input processor, database index shared access memory loader, reference data buffer and data managers may include a software application stored in one or more of the disk drives connected to the disk controller 890, the ROM 858 and/or the RAM 859. The processor 854 may access one or more components as required. A display interface 887 may permit information from the bus 852 to be displayed on a display 880 in audio, graphic, or alphanumeric format. Communication with external devices may optionally occur using various communication ports 882. In addition to these computer-type components, the hardware may also include data input devices, such as a keyboard 879, or other input device 1381, such as a microphone, remote control, pointer, mouse and/or joystick.

Additionally, the methods and systems described herein may be implemented on many different types of processing devices by program code comprising program instructions that are executable by the device processing subsystem. The software program instructions may include source code, object code, machine code, or any other stored data that is operable to cause a processing system to perform the methods and operations described herein and may be provided in any suitable language such as C, C++, JAVA, for example, or any other suitable programming language. Other implementations may also be used, however, such as firmware or even appropriately designed hardware configured to carry out the methods and systems described herein.

The systems' and methods' data (e.g., associations, mappings, data input, data output, intermediate data results, final data results, etc.) may be stored and implemented in one or more different types of computer-implemented data stores, such as different types of storage devices and programming constructs (e.g., RAM, ROM, Flash memory, flat files, databases, programming data structures, programming variables, IF-THEN (or similar type) statement constructs, etc.). It is noted that data structures describe formats for use in organizing and storing data in databases, programs, memory, or other computer-readable media for use by a computer program.

The computer components, software modules, functions, data stores and data structures described herein may be connected directly or indirectly to each other in order to allow the flow of data needed for their operations. It is also noted that a module or processor includes but is not limited to a unit of code that performs a software operation, and can be implemented for example as a subroutine unit of code, or as a software function unit of code, or as an object (as in an object-oriented paradigm), or as an applet, or in a computer script language, or as another type of computer code. The software components and/or functionality may be located on a single computer or distributed across multiple computers depending upon the situation at hand.

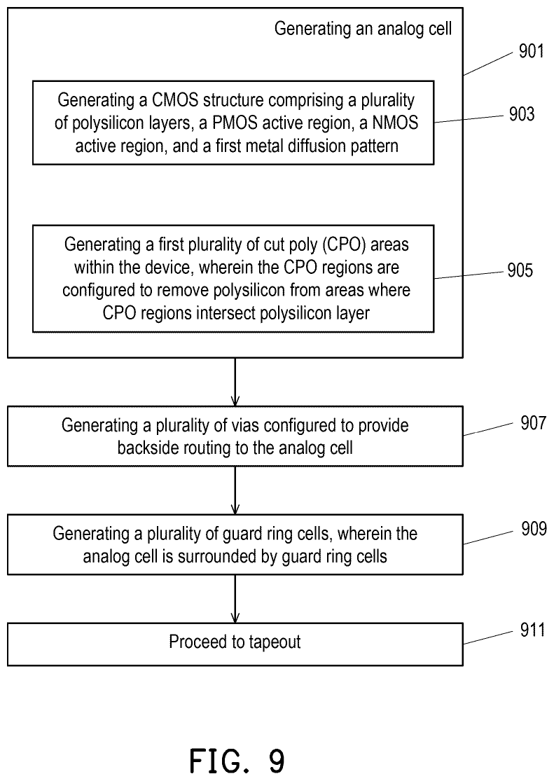

FIG. 9 is a flowchart depicting a method of designing an analog circuit according to an embodiment. The method may begin at 901 with an IC design tool generating an analog cell. In an embodiment, the analog cell may be a cell as described above with reference to FIGS. 3-5. For example, and as shown at 903, generating the analog cell may comprise generating a CMOS structure comprising a plurality of polysilicon layers, a PMOS active region, a NMOS active region, and a first metal diffusion pattern. Additionally, as shown at 905, generating the analog cell may comprise generating a first plurality of cut poly (CPO) areas within the device, wherein the CPO regions are configured to remove polysilicon from areas where CPO regions intersect polysilicon layer.

The method may further comprise generating a plurality of vias configured to provide backside routing to the analog cell as shown at 907. The plurality of vias may comprise feed-through vias and backside vias configured to provide P/G and/or signal connections to components of the analog cell through the backside.

At 909, the method may further comprise generating a plurality of guard ring cells, wherein the analog cell is surrounded by the guard ring cells. For example, as shown in FIG. 2 and described above, each analog cell in an analog circuit design may be surrounded by eight guard ring cells. These guard ring cells may comprise the components as shown in FIGS. 5-7 and described above. The method may further comprise proceeding to tapeout at 911.

FIG. 10 is a flowchart depicting a method of fabricating an integrated circuit device according to an embodiment.

The method may begin at 1001 by generating an analog circuit design. The analog circuit design may be similar to those shown in FIGS. 2-7 and described above. For example, the design may comprise a bottom metal routing layer comprising a plurality of tracks, an analog circuit comprising NMOS and PMOS active regions, a plurality of polysilicon layers, a plurality of metal diffusion layers, and a plurality of cut poly (CPO) areas. The NMOS active region, PMOS active region, plurality of polysilicon layers, and plurality of metal diffusion layers make up a CMOS structure. In an embodiment, a first CPO area of the plurality of CPO areas and a first polysilicon layer of the plurality of polysilicon layers comprise a first overlap.

The analog circuit design may further comprise a plurality of guard ring cells surrounding the analog cell, and a power rail structure configured to provide connection between the bottom metal routing layer and the analog cell.

Optionally, the method may further comprise performing design rule checks as shown at 1003. By incorporating features described above (e.g., CPO/CMD design, PODE and CNOD diffusion regions, etc.) devices fabricated according to embodiments described herein may comprise a reduced size without violating any design rules.

At 1005, the method may proceed initiating fabrication of a device based on the analog circuit design. Fabricating the device may comprise forming an analog cell comprising a CMOS structure and forming a polysilicon guard ring structure in a region corresponding to at least one of the guard ring cells. Forming the CMOS structure of the analog cell may comprise depositing a plurality of polysilicon layers corresponding to the PO layers of the design. In an embodiment these layers may be subject to further processing as described below with respect to FIGS. 10B-10K.

At 1007, the method of fabricating a device may further comprises replacing the polysilicon layers in the analog cell with metal gate structures. The replacement process may comprise an etching process that removes the polysilicon layers without damaging other structures in the device. The space left by this removal may then be filled by depositing a metal material. The metal material may form a metal gate electrode of one or more transistors.

At 1009, the method may further comprise performing a cut metal gate (CMG) process. The cut metal gate process may remove the deposited metal at predetermined locations. In an embodiment these predetermined locations correspond with the locations of the CPO regions in the design. The cut metal gate process may allow the metal gate electrodes to be divided into individual components and provide a smaller pitch as compared to other processes.

At 1011, the method may further comprise forming a backside routing structure to provide a connection to the device. For example the backside routing structure may comprise a bottom metal routing layer and backside via so as to route signals to transistors in the analog cell.

FIGS. 10B-10K are schematic diagrams depicting cross-sectional views of a method of fabricating an integrated circuit device according to an embodiment. FIGS. 10B, 10D, 10F, 10H, and 10J depict a first cross-section along a PO layer of a cell as described above. FIGS. 10C, 10E, 10G, and 10I depict a second cross-section that is perpendicular to the first cross-section.

FIGS. 10B-10K may depict structures similar to those described above with respect to FIGS. 3C-3D. For example, as shown in FIG. 10B-10C, fabrication of an analog cell may comprise depositing a polysilicon layer 1035 over a plurality of fins 1022, 1024 extending from a dielectric 1090. In an embodiment, the polysilicon layer 1035 may be a dummy electrode layer and may be separated from the fins and underlying substrate by a gate dielectric layer 1060. Gate dielectric layer may be a high-k dielectric material. Gate spacers 1062 may also be formed on either side of the polysilicon layer 1035.

FIGS. 10D-10E may depict element 1007 of FIG. 10A. As shown in FIGS. 10D and 10E, the polysilicon layer 1035 may be removed. This removal may be selective to the material of the deposited dummy electrode layer. For example, the removal process may remove polysilicon 1035 selective to the gate dielectric layer 1060 and gate spacers 1062. In other embodiments, the gate dielectric 1060 may also be removed and replaced by a replacement gate dielectric layer. While embodiments described herein refer to polysilicon, other dummy materials may used. Removal of the polysilicon layer 1035 may comprise one or more etching process such as dry etching, wet etching, reactive ion etching, or other suitable etching methods.

FIGS. 10F-10G may depict another aspect of element 1007 of FIG. 10A. As shown in FIGS. 10F-10G, a replacement metal gate 1068 may be formed to replace polysilicon layer 1035. The replacement metal gate 1068 may comprise one or more seed layers, barrier layers, and/or work function metal layers, along with a metal fill layer, and may be deposited using methods such as CVD, PVD, plating, and/or other suitable processes. Forming the replacement metal gate 1068 may further comprise a planarization process such as a chemical mechanical polishing (CMP) and/or other suitable processes so as to form the replacement gate 1068 to a desired height.

FIGS. 10H-10I may depict element 1009 of FIG. 10A in which a cut metal gate process may be performed. In an embodiment, this process may comprise forming a mask 1066 over the replacement gate 1068. Mask 1066 may comprise a patterned mask including gaps 1061 corresponding to the location of the CPO regions in the design. For example, mask 1066 may be a patterned hard mask.

As shown in FIGS. 10J-10K, the cut metal gate process may further comprise performing an etching through this hard mask to remove portions of the replacement gate 1068 under gaps 1061. The etching process may comprise wet etching, dry etching, reactive ion etching, or other suitable etching methods. Such gate cut regions where the replacement gate 1068 is removed may divide a deposited metal gate structure into individual parts in order to form desired transistor structures within a device. For example, the gate cuts may allow for a CMOS structure to be formed in an analog cell region of a fabricated device. Thereafter, and as described above with respect to element 1011 of FIG. 10A, a backside routing structure may be applied so as to route signals to and from the analog cell.

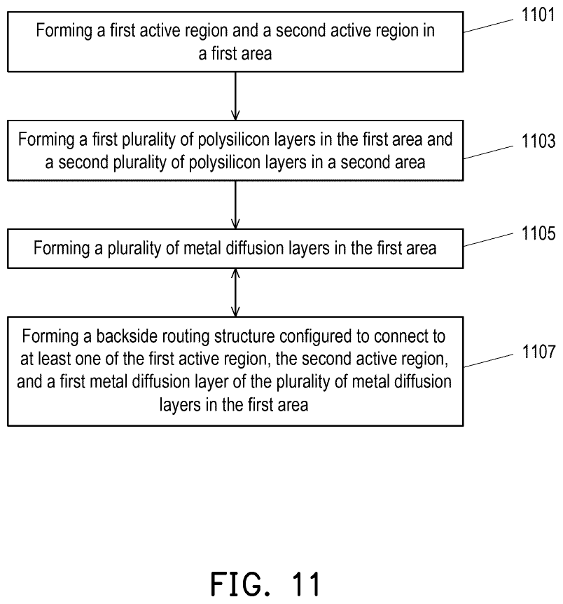

FIG. 11 is a flowchart depicting a method of fabricating an integrated device according to an integrated circuit. At 1101, a first active region and a second active region may be formed in a first area of an integrated circuit device. For example, the first area may correspond with an analog cell region of an integrated circuit device, as described above with respect to FIG. 2, for example. The first active region and second active region may comprise doped regions corresponding to source, drain, and channel regions of a transistor, as described above with respect to FIGS. 3A-3D, for example.

At 1103, a first plurality of polysilicon layers may be formed in the first area and a second plurality of polysilicon layers may be formed in a second area of the integrated circuit device. The second area may correspond with a guard ring cell region of the integrated circuit device. In an embodiment, each analog cell region may be surrounded by a plurality of guard ring cell regions. The first plurality of polysilicon layers may comprise gate or dummy gate layers of transistors formed within the analog cell of the first area, as described above with respect to FIGS. 3A-3D and/or FIGS. 10B-10K, for example. The second plurality of polysilicon layers may comprise a polysilicon guard ring formed in the guard ring cell of the second area.

At 1105, a first plurality of metal diffusion layers may be formed in the first area. The metal diffusion layers may provide routing for structures within the analog cell of the first area. For example the metal diffusion layers may comprise source/drain metallization structures as shown in FIG. 2, for example, and may be configured to connect the analog cell to upper level routing.

In an embodiment, forming the plurality of polysilicon layers and plurality of metal diffusion layers comprise generating cut poly (CPO) regions and cut metal diffusion (CMD) regions. The CPO and CMD regions are generated so as to overlap with a pattern of polysilicon layers and a pattern of metal diffusion layers, respectively. During fabrication, these overlap regions may be removed from the polysilicon and metal diffusion patterns to generate the final disposition of the polysilicon layers and metal diffusion layers. This process may proceed as described above with reference to FIGS. 10B-10K. Alternatively or additionally, the polysilicon layers in the first area may be removed and replaced with a metal gate material to form metal gate electrodes.

Through these processes, an analog cell may be formed in the first area. In an embodiment, the analog cell may comprise a CMOS structure including an NMOS active region and a PMOS active region corresponding to the first active region and the second active region. In an embodiment, forming the analog cell may comprise forming an n-type metal oxide semiconductor (NMOS) active region and a p-type metal oxide semiconductor (PMOS) active region, forming a plurality of polysilicon layers and forming a plurality of metal diffusion layers. Taken together, the NMOS active region, PMOS active region, polysilicon layers, and metal diffusion layers may form the CMOS structure of the cell. The active regions may comprise source/drain regions and a channel layer. For example, with reference to FIGS. 1A-1B, forming the NMOS and PMOS active regions may comprise forming source/drain elements 112.

At 1107, a backside routing structure may be formed. The backside routing structure may be configured to connect to at least one of the first active region, the second active region, and a first metal diffusion layer of the plurality of metal diffusion layers in the first area. In an embodiment, the backside routing structure comprises a power rail structure that is configured to provide a connection between a track of a bottom metal routing layer and structures within the analog cell. In an embodiment, the power rail structure routing may comprise a plurality of feed through vias and a plurality of backside vias. For example, with reference to FIGS. 1A-1B, the backside routing may comprise a feedthrough via 115 and a backside via 120. The backside routing may carry signals between the first metal routing layer BM0 and components within the analog cell, such as source/drain regions 112 or metal diffusion layers 103.

In the second area, a plurality of guard ring cells may be formed. In an embodiment, the plurality of guard ring cells may be formed such that the analog cell is surrounded by guard ring cells. For example, with reference to FIG. 2, an integrated circuit may comprise a plurality of analog cells and each analog cell may be surrounded on all sides by guard ring cells of the plurality of guard ring cells. As such, the guard ring cells may provide protection and isolation for the analog cells. As described with respect to FIGS. 5 and 6, for example, forming the plurality of guard ring cells may comprise generating CPO and CMD regions within the guard ring cells and removing polysilicon and metal diffusion patterns in areas that overlap with the CPO and CMD regions. Thus, according to the method described above, an integrated circuit device may be formed that comprises an analog cell having backside routing that is surrounded by guard ring cells.

Devices and methods are described herein. In an example device, an analog circuit device comprises a bottom metal routing layer comprising a plurality of tracks, an analog cell comprising an n-type metal oxide semiconductor (NMOS) active region and a p-type metal oxide semiconductor (PMOS) active region, a plurality of polysilicon layers, and a plurality of metal diffusion layers, wherein the NMOS active region, PMOS active region, plurality of polysilicon layers, and plurality of metal diffusion layers make up a CMOS structure. The active regions may comprise source/drain regions and/or channel regions and the active regions may include diffused dopants. The analog circuit device further comprises a plurality of guard ring cells surrounding the analog cell, and a power rail structure configured to provide connection between the bottom metal routing layer and the analog cell.

In an example method of fabricating an analog circuit, a fist active region and a second active region are formed in a first area. A first plurality of polysilicon layers are formed in the first area and a second plurality of polysilicon layers are formed in a second area. A plurality of metal diffusion layers is also formed in the first area. A backside routing structure is formed that is configured to connect to at least one of the first active region, the second active region and a first metal diffusion layer of the plurality of metal diffusion layers in the first area. In the method, the first area comprises an analog cell and the second area comprises a guard ring cell.

In an example structure an analog cell structure is provided. The analog cell structure comprises a first feed-through via and a second feed-through via extending in a first direction and separated by a first distance in a second direction perpendicular to the first direction and a CMOS structure disposed between the first feed-through via and the second feed-through via and comprising a plurality of polysilicon layers, a PMOS active region, a NMOS active region, and a first metal diffusion pattern. The structure further includes a metal routing layer and a plurality of vias. The first feed-through via, the second feed-through via, and a first via of the plurality of vias are configured to provide backside connection to the CMOS structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An analog circuit device, comprising:
a metal routing layer comprising a plurality of tracks;
an analog cell comprising an n-type metal oxide semiconductor (NMOS) active region and a p-type metal oxide semiconductor (PMOS) active region, a plurality of polysilicon layers, and a plurality of metal diffusion layers, wherein the NMOS active region, PMOS active region, plurality of polysilicon layers, and plurality of metal diffusion layers make up a CMOS structure;
a plurality of guard ring cells surrounding the analog cell; and
a power rail structure configured to provide backside routing to the analog cell by providing a connection between the metal routing layer and the analog cell.

2. The device of claim 1, wherein the rail structure comprises at least one feed-through via and at least one backside via.

3. The device of claim 2, wherein the at least one feed-through via comprises a first feed-through via and a second feed-through via extending in a first direction and separated in a second direction, and
wherein the analog cell is disposed between the first feed-through via and the second feed-through via.

4. The device of claim 3, further comprising a first break region in the first feed-through via and a second break region in the second feed-through,
wherein at least one polysilicon layer of the plurality of polysilicon layers is tied off in the first break region and the second break region.

5. The device of claim 1, wherein the analog cell comprises one of a plurality of analog cells;
the plurality of analog cells and the plurality of guard ring cells are arranged in an array comprising rows and columns; and
the cells are arranged such that each analog cell of the plurality of analog cells is surrounded by guard ring cells of the plurality of guard ring cells.

6. The device of claim 5, wherein the plurality of guard ring cells comprises an outer border of guard ring cells comprising:
four corner guard ring cells;
at least one horizontal guard ring cell; and
at least one vertical guard ring cell,
wherein a first corner guard ring cell of the four corner guard ring cells comprises a first guard ring structure;
the at least one vertical guard ring cell is adjacent to the first corner guard ring cell and comprises a second guard ring structure; and
wherein the first guard ring structure interfaces with the second guard ring structure.

7. The device of claim 6, further comprising a third guard ring structure within a second corner guard ring cell, wherein the at least one vertical guard ring cell is disposed between the first corner guard ring cell and the second corner guard ring cell.

8. The device of claim 1, wherein the NMOS active region and the PMOS active region of the analog cell extend outside of the cell boundary.

9. The device of claim 1, wherein a first guard ring cell of the plurality of guard ring cells comprises a guard ring structure; and
the guard ring structure comprises a dummy structure.

10. The device of claim 1, wherein a first guard ring cell of the plurality of guard ring cells comprises a guard ring structure; and
the guard ring structure comprises an oxide structure.

11. The device of claim 1, wherein the power rail structure comprises a feed-through via disposed between a first track of the plurality of tracks and a portion of a first metal diffusion layer of the plurality of the metal diffusion layers and a backside via disposed between a second track of the plurality of tracks and one of the PMOS active region and the NMOS active region.

12. A method of fabricating an integrated circuit comprising:
forming a first active region and a second active region in a first area;
forming a first plurality of polysilicon layers in the first area and a second plurality of polysilicon layers in a second area;
forming a plurality of metal diffusion layers in the first area; and
forming a backside routing structure configured to connect to at least one of the first active region, the second active region and a first metal diffusion layer of the plurality of metal diffusion layers in the first area,
wherein the first area comprises an analog cell and the second area comprises a guard ring cell.

13. The method of claim 12, further comprising:
removing the first plurality of polysilicon layers and forming a plurality of replacement metal gate structures.

14. The method of claim 12, wherein the guard ring cell is a first guard ring cell of a plurality of guard ring cells and the analog cell is surrounded by the plurality of guard ring cells.

15. The method of claim 14, wherein the second plurality of polysilicon layers comprises a polysilicon guard ring.

16. The method of claim 14, wherein the polysilicon guard ring comprises a rectangular shape with an internal extension.

17. The method of claim 12, wherein forming the backside routing structure comprises:
forming a plurality of feed-through vias extending in a first direction and separated in a second direction; and
forming a plurality of backside vias extending in a third direction.

18. The method of claim 16, wherein the analog cell is formed to extend between a first feed-through via and a second feed-through via.

19. An analog cell structure, comprising:
a first feed-through via and a second feed-through via extending in a first direction and separated by a first distance in a second direction perpendicular to the first direction;
a CMOS structure disposed between the first feed-through via and the second feed-through via and comprising a plurality of polysilicon layers, a PMOS active region, a NMOS active region, and a first metal diffusion pattern;
a metal routing layer; and
a plurality of vias,
wherein the first feed-through via, the second feed-through via, and a first via of the plurality of vias are configured to provide backside connection to the CMOS structure.

20. The structure of claim 19, wherein the analog cell structure is disposed adjacent to a guard ring cell comprising a guard ring structure.
